(19) United States
(12) Patent Application Publication
(10) Pub. No.: US 2023/0335404 A1
(43) Pub. Date: Oct. 19, 2023

(54) SUBSTRATE PROCESSING METHOD, NON-TRANSITORY COMPUTER-READABLE RECORDING MEDIUM, SUBSTRATE PROCESSING APPARATUS AND METHOD OF MANUFACTURING SEMICONDUCTOR DEVICE

(71) Applicant: Kokusai Electric Corporation, Tokyo (JP)

(72) Inventors: Arito OGAWA, Toyama (JP); Atsuro SEINO, Toyama (JP)

(21) Appl. No.: 18/336,573

(22) Filed: Jun. 16, 2023

Related U.S. Application Data
(63) Continuation of application No. PCT/JP2020/047104, filed on Dec. 17, 2020.

(51) Int. Cl. H01L 21/285; C23C 16/34; C23C 16/14; C23C 16/56

(52) U.S. Cl. CPC H01L 21/28568; C23C 16/345; C23C 16/14; C23C 16/56

(57) ABSTRACT

According to the present disclosure, there is provided a technique capable of improving film properties. According to one aspect of the technique of the present disclosure, there is provided a substrate processing method including: preparing a substrate comprising a first film containing a first metal element and a second film containing a Group 13 element or a Group 14 element and formed on the first film; and forming a third film containing a second metal element on the substrate while removing at least part of the second film by performing: supplying a gas containing the second metal element to the substrate; and supplying a first reactive gas to the substrate.

### CROSS REFERENCE TO RELATED APPLICATIONS

This application is a bypass continuation application of PCT International Application No. PCT/JP2020/047104, filed on Dec. 17, 2020, in the WIPO, the entire contents of which are hereby incorporated by reference.

### TECHNICAL FIELD

The present disclosure relates to a substrate processing method, a non-transitory computer-readable recording medium, a substrate processing apparatus and a method of manufacturing semiconductor device.

### BACKGROUND

Recently, as a semiconductor device is highly integrated and a performance thereof is increased, various types of metal films may be used to manufacture a semiconductor device of a three-dimensional structure. For example, a film such as a tungsten film (W film) is used as a control gate of a NAND flash memory serving as an example of the semiconductor device of the three-dimensional structure. Further, according to some related arts, for example, a titanium nitride film (TiN film) may be used as a barrier film between the W film and an insulating film.

However, when a second metal film such as the W film is formed on a surface of a first metal film such as the TiN film, the surface of the first metal film may be etched by a film-forming gas used to form the second metal film. When the surface of the first metal film is etched, film properties thereof may deteriorate.

### SUMMARY

According to the present disclosure, there is provided a technique capable of improving film properties.

According to one aspect of the technique of the present disclosure, there is provided a substrate processing method including: (A) preparing a substrate comprising a first film containing a first metal element and a second film containing a Group 13 element or a Group 14 element and formed on the first film; and (B) forming a third film containing a second metal element on the substrate while removing at least part of the second film by performing: (a) supplying a gas containing the second metal element to the substrate; and (b) supplying a first reactive gas to the substrate.

### BRIEF DESCRIPTION OF THE DRAWINGS

FIG. 1 is a diagram schematically illustrating a vertical cross-section of a process furnace 202a of a substrate processing apparatus 10 according to one or more embodiments of the present disclosure.

FIG. 2 is a diagram schematically illustrating a horizontal cross-section, taken along a line A-A shown in FIG. 1, of the process furnace 202a of the substrate processing apparatus 10 according to the embodiments of the present disclosure.

FIG. 3 is a diagram schematically illustrating a vertical cross-section of a process furnace 202b of the substrate processing apparatus 10 according to the embodiments of the present disclosure.

FIG. 4 is a diagram schematically illustrating a horizontal cross-section, taken along a line A-A shown in FIG. 3, of the process furnace 202b of the substrate processing apparatus 10 according to the embodiments of the present disclosure.

FIG. 5 is a block diagram schematically illustrating a configuration of a controller and related components of the substrate processing apparatus 10 according to the embodiments of the present disclosure.

FIG. 6 is a diagram schematically illustrating a process sequence of a substrate processing performed in the process furnace 202a of the substrate processing apparatus 10 according to the embodiments of the present disclosure.

FIG. 7 is a diagram schematically illustrating a process sequence of the substrate processing performed in the process furnace 202b of the substrate processing apparatus 10 according to the embodiments of the present disclosure.

FIGS. 8A and 8B are diagrams schematically illustrating a film (films) formed on a substrate by performing the substrate processing in the process furnace 202a, and FIG. 8C is a diagram schematically illustrating films formed on the substrate after performing the substrate processing in the process furnace 202b.

FIG. 9 is a diagram schematically illustrating a modified example of the process sequence of the substrate processing performed in the process furnace 202b of the substrate processing apparatus 10 according to the embodiments of the present disclosure.

FIG. 10A is a diagram schematically illustrating structures of samples (that is, a “SAMPLE #1” and a “SAMPLE #2”) used in the embodiments of the present disclosure, and FIGS. 10B and 10C are diagrams schematically illustrating XPS (X-ray Photoelectron Spectroscopy) analysis results of the SAMPLE #1 and the SAMPLE #2 shown in FIG. 10A.

FIG. 11A is a diagram schematically illustrating the structures of the samples (that is, a “SAMPLE #1” and a “SAMPLE #2” after the substrate processing is performed in the process furnace 202b) used in the embodiments of the present disclosure, and FIGS. 11B and 11C are diagrams schematically illustrating XPS analysis results of the SAMPLE #1 and the SAMPLE #2 shown in FIG. 11A.

### DETAILED DESCRIPTION

### Embodiments of Present Disclosure

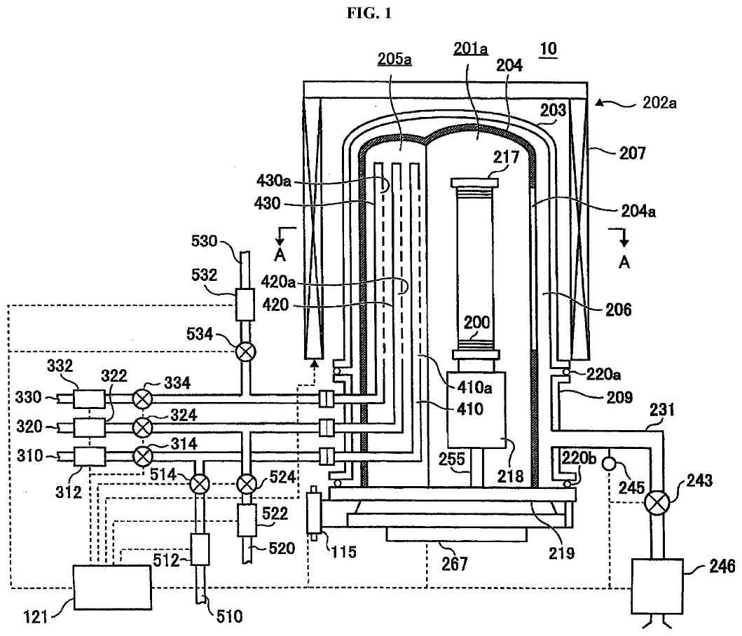

Hereinafter, one or more embodiments (also simply referred to as “embodiments”) according to the technique of the present disclosure will be described with reference to FIGS. 1 through 7 and FIGS. 8A through 8C. A substrate processing apparatus 10 is configured as an example of an apparatus used in a manufacturing process of a semiconductor device. In the present specification, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

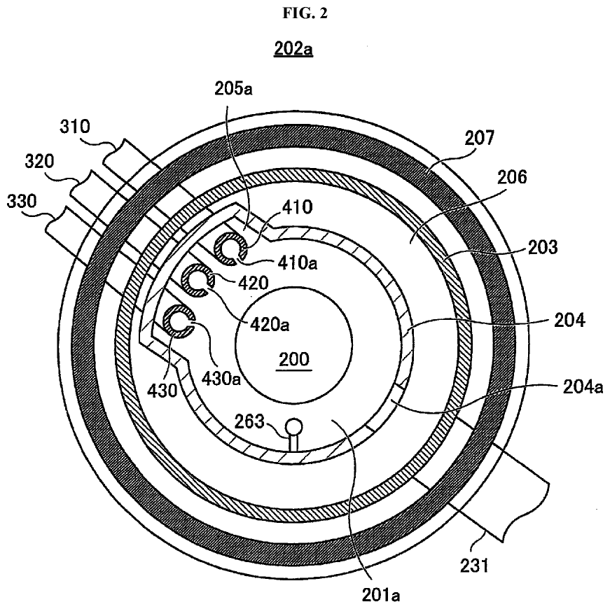

FIG. 1 is a diagram schematically illustrating a vertical cross-section of a process furnace 202a serving as a first process structure provided in a substrate processing apparatus (hereinafter, also simply referred to as the “substrate processing apparatus 10”) capable of performing a method of manufacturing the semiconductor device (that is, the manufacturing process of a semiconductor device), and FIG. 2 is a diagram schematically illustrating a horizontal cross-section, taken along a line A-A shown in FIG. 1, of the process furnace 202a of the substrate processing apparatus 10. Hereinafter, the present embodiments will be described by way of an example in which, after forming a first metal-containing film on a wafer 200 and a cap film on the first metal-containing film in the process furnace 202a serving as the first process structure, a second metal-containing film is formed in a process furnace 202b serving as a second process structure described later while removing at least part of the cap film formed on the first metal-containing film.

The process furnace 202a is provided with a heater 207 serving as a heating structure (which is a heating device, a heating apparatus or a heating system). The heater 207 is of a cylindrical shape, and is vertically installed while being supported by a heater base (not shown) serving as a support plate.

An outer tube 203 constituting a reaction vessel (which is a process vessel) is provided in an inner side of the heater 207 to be aligned in a manner concentric with the heater 207. For example, the outer tube 203 is made of a heat resistant material such as quartz (SiO₂) and silicon carbide (SiC). The outer tube 203 is of a cylindrical shape with a closed upper end and an open lower end. A manifold (which is an inlet flange) 209 is provided under the outer tube 203 to be aligned in a manner concentric with the outer tube 203. For example, the manifold 209 is made of a metal such as stainless steel (SUS). The manifold 209 is of a cylindrical shape with open upper and lower ends. An O-ring 220a serving as a seal is provided between the upper end of the manifold 209 and the outer tube 203. As the manifold 209 is supported by the heater base (not shown), the outer tube 203 is installed vertically.

An inner tube 204 constituting the reaction vessel is provided in an inner side of the outer tube 203. For example, the inner tube 204 is made of a heat resistant material such as quartz (SiO₂) and silicon carbide (SiC). The inner tube 204 is of a cylindrical shape with a closed upper end and an open lower end. The process vessel (reaction vessel) is constituted mainly by the outer tube 203, the inner tube 204 and the manifold 209. A process chamber 201a is provided in a hollow cylindrical portion of the process vessel (that is, an inner side of the inner tube 204). The present embodiments will be described by way of an example in which the process vessel (reaction vessel) includes the inner tube 204 (that is, the process chamber 201a is provided in the inner side of the inner tube 204). However, the present embodiments may also be applied when the process vessel (reaction vessel) does not include the inner tube 204.

The process chamber 201a is configured to be capable of accommodating a plurality of wafers including the wafer 200 serving as a substrate in a horizontal orientation to be vertically arranged in a multistage manner by a boat 217 described later. Hereinafter, the plurality of wafers including the wafer 200 may also be simply referred to as “wafers 200”.

Nozzles 410, 420 and 430 are installed in the process chamber 201a so as to penetrate a side wall of the manifold 209 and the inner tube 204. Gas supply pipes 310, 320 and 330 serving as gas supply lines are connected to the nozzles 410, 420 and 430, respectively. As described above, for example, the three nozzles 410, 420 and 430 and the three gas supply pipes 310, 320 and 330 are provided at the substrate processing apparatus 10, and thereby it is possible to supply various gases into the process chamber 201a through the three nozzles 410, 420 and 430 and the three gas supply pipes 310, 320 and 330. However, the process furnace 202a of the present embodiments is not limited to an exemplary configuration described above.

Mass flow controllers (MFCs) 312, 322 and 332 serving as flow rate controllers (flow rate control structures) and valves 314, 324 and 334 serving as opening/closing valves are sequentially installed at the gas supply pipes 310, 320 and 330 in this order from upstream sides to downstream sides of the gas supply pipes 310, 320 and 330 in a gas flow direction, respectively. Gas supply pipes 510, 520 and 530 through which an inert gas is supplied are connected to the gas supply pipes 310, 320 and 330 at downstream sides of the valves 314, 324 and 334, respectively. MFCs 512, 522 and 532 and valves 514, 524 and 534 are sequentially installed at the gas supply pipes 510, 520 and 530 in this order from upstream sides to downstream sides of the gas supply pipes 510, 520 and 530 in the gas flow direction, respectively.

The nozzles 410, 420 and 430 are connected to front ends (tips) of the gas supply pipes 310, 320 and 330, respectively. Each of the nozzles 410, 420 and 430 may be configured as an L-shaped nozzle. Horizontal portions of the nozzles 410, 420 and 430 are installed so as to penetrate the side wall of the manifold 209 and the inner tube 204. Vertical portions of the nozzles 410, 420 and 430 are installed in a spare chamber (which is a preliminary chamber) 205a of a channel shape (a groove shape) protruding outward in a radial direction of the inner tube 204 and extending in a vertical direction. That is, the vertical portions of the nozzles 410, 420 and 430 are installed in the spare chamber 205a toward the upper end of the inner tube 204 (in a direction in which the wafers 200 are arranged) and along an inner wall of the inner tube 204.

The nozzles 410, 420 and 430 extend from a lower region of the process chamber 201a to an upper region of the process chamber 201a. The nozzles 410, 420 and 430 are provided with a plurality of gas supply holes 410a, a plurality of gas supply holes 420a and a plurality of gas supply holes 430a, respectively, at positions facing the wafers 200. Thereby, a gas such as a process gas can be supplied to the wafers 200 through the gas supply holes 410a of the nozzle 410, the gas supply holes 420a of the nozzle 420 and the gas supply holes 430a of the nozzle 430. The gas supply holes 410a, the gas supply holes 420a and the gas supply holes 430a are provided from a lower portion to an upper portion of the inner tube 204. An opening area of each of the gas supply holes 410a, the gas supply holes 420a and the gas supply holes 430a is the same, and each of the gas supply holes 410a, the gas supply holes 420a and the gas supply holes 430a is provided at the same pitch. However, the gas supply holes 410a, the gas supply holes 420a and the gas supply holes 430a are not limited thereto. For example, the opening area of each of the gas supply holes 410a, the gas supply holes 420a and the gas supply holes 430a may gradually increase from the lower portion to the upper portion of the inner tube 204 to further uniformize a flow rate of the gas supplied through the gas supply holes 410a, the gas supply holes 420a and the gas supply holes 430a.

The gas supply holes 410a of the nozzle 410, the gas supply holes 420a of the nozzle 420 and the gas supply holes 430a of the nozzle 430 are provided from a lower portion to an upper portion of the boat 217 described later. Therefore, the process gas supplied into the process chamber 201a through the gas supply holes 410a of the nozzle 410, the gas supply holes 420a of the nozzle 420 and the gas supply holes 430a of the nozzle 430 is supplied onto the wafers 200 accommodated in the boat 217 from the lower portion to the upper portion thereof, that is, an entirety of the wafers 200 accommodated in the boat 217. The nozzles 410, 420 and 430 may extend from the lower region to the upper region of the process chamber 201a. However, it is preferable that the nozzles 410, 420 and 430 extend to the vicinity of a ceiling of the boat 217.

A gas containing a first metal element (hereinafter, also referred to as a “first metal-containing gas”) serving as one of process gases is supplied into the process chamber 201a through the gas supply pipe 310 provided with the MFC 312 and the valve 314 and the nozzle 410.

A third reactive gas (which reacts with the first metal-containing gas) serving as one of the process gases is supplied into the process chamber 201a through the gas supply pipe 320 provided with the MFC 322 and the valve 324 and the nozzle 420. In the present disclosure, the present embodiments will be described by way of an example in which the third reactive gas is also used as a reactive gas that reacts with a gas (which is described later) containing a Group 13 element or a Group 14 element.

The gas containing the Group 13 element or the Group 14 element (which serves as one of the process gases) is supplied into the process chamber 201a through the gas supply pipe 330 provided with the MFC 332 and the valve 334 and the nozzle 430.

For example, as the inert gas, nitrogen gas (N2 gas) is supplied into the process chamber 201a through the gas supply pipes 510, 520 and 530 provided with the MFCs 512, 522 and 532 and the valves 514, 524 and 534, respectively, and the nozzles 410, 420 and 430. While the present embodiments will be described by way of an example in which the N₂ gas is used as the inert gas, the inert gas according to the present embodiments is not limited thereto. For example, instead of the N₂ gas or in addition to the N2 gas, a rare gas such as argon (Ar) gas, helium (He) gas, neon (Ne) gas and xenon (Xe) gas may be used as the inert gas.

A process gas supplier (which is a process gas supply structure or a process gas supply system) is constituted mainly by the gas supply pipes 310, 320 and 330, the MFCs 312, 322 and 332, the valves 314, 324 and 334 and the nozzles 410, 420 and 430. However, it is also possible for the nozzles 410, 420 and 430 alone to be referred to as the process gas supplier. The process gas supplier may also be simply referred to as a “gas supplier” which is a gas supply structure or a gas supply system. When the first metal-containing gas is supplied through the gas supply pipe 310, a first metal-containing gas supplier (which is a first metal-containing gas supply structure or a first metal-containing gas supply system) is constituted mainly by the gas supply pipe 310, the MFC 312 and the valve 314. The first metal-containing gas supplier may further include the nozzle 410. Further, when the third reactive gas is supplied through the gas supply pipe 320, a third reactive gas supplier (which is a third reactive gas supply structure or a third reactive gas supply system) is constituted mainly by the gas supply pipe 320, the MFC 322 and the valve 324. The third reactive gas supplier may further include the nozzle 420. When a nitrogen-containing gas serving as the third reactive gas is supplied through the gas supply pipe 320, the third reactive gas supplier may also be referred to as a “nitrogen-containing gas supplier” which is a nitrogen-containing gas supply structure or a nitrogen-containing gas supply system. Further, when the gas containing the Group 13 element or the Group 14 element is supplied through the gas supply pipe 330, a supplier (which is a supply structure or a supply system) for the gas containing the Group 13 element or the Group 14 element is constituted mainly by the gas supply pipe 330, the MFC 332 and the valve 334. However, it is also possible for the nozzle 430 alone to be referred to as the supplier for the gas containing the Group 13 element or the Group 14 element. In addition, an inert gas supplier (which is an inert gas supply structure or an inert gas supply system) is constituted mainly by the gas supply pipes 510, 520 and 530, the MFCs 512, 522 and 532 and the valves 514, 524 and 534.

According to the present embodiments, the gas is supplied into a vertically long annular space (that is, a cylindrical space) which is defined by the inner wall of the inner tube 204 and edges (peripheries) of the wafers 200 through the nozzles 410, 420 and 430 provided in the spare chamber 205a. The gas is ejected into the inner tube 204 through the gas supply holes 410a of the nozzle 410, the gas supply holes 420a of the nozzle 420 and the gas supply holes 430a of the nozzle 430 facing the wafers 200. Specifically, gases such as the process gases are ejected into the inner tube 204 in a direction parallel to surfaces of the wafers 200 (that is, in a horizontal direction) through the gas supply holes 410a of the nozzle 410, the gas supply holes 420a of the nozzle 420 and the gas supply holes 430a of the nozzle 430, respectively.

An exhaust hole (which is an exhaust port) 204a is a through-hole facing the nozzles 410, 420 and 430, and is provided at a side wall of the inner tube 204. That is, the exhaust hole 204a is provided at a location opposite to the spare chamber 205a by 180°. For example, the exhaust hole 204a may be of a narrow slit-shaped through-hole elongating vertically. The gas supplied into the process chamber 201a through the gas supply holes 410a of the nozzle 410, the gas supply holes 420a of the nozzle 420 and the gas supply holes 430a of the nozzle 430 flows over the surfaces of the wafers 200. Then, the gas that has flowed over the surfaces of the wafers 200 (that is, a residual gas) is exhausted through the exhaust hole 204a into a gap (that is, an exhaust path 206) provided between the inner tube 204 and the outer tube 203. Then, the gas flowing in the exhaust path 206 flows into an exhaust pipe 231 and is then discharged (exhausted) out of the process furnace 202a.

The exhaust hole 204a is provided at a location facing the wafers 200 (preferably, at a location facing the upper portion through the lower portion of the boat 217). The gas supplied in the vicinity of the wafers 200 in the process chamber 201a through the gas supply holes 410a, the gas supply holes 420a and the gas supply holes 430a flows in the horizontal direction (that is, in the direction parallel to the surfaces of the wafers 200). The gas that has flowed in the horizontal direction is exhausted through the exhaust hole 204a into the exhaust path 206. That is, the gas remaining in the process chamber 201a (that is, the residual gas) is exhausted in parallel with main surfaces of the wafers 200 through the exhaust hole 204a. The exhaust hole 204a is not limited to the slit-shaped through-hole. For example, the exhaust hole 204a may be configured as a plurality of holes.

The exhaust pipe 231 through which an inner atmosphere of the process chamber 201a is exhausted is installed at the manifold 209. A pressure sensor 245 serving as a pressure detector (which is a pressure detecting structure) configured to detect an inner pressure of the process chamber 201a, an APC (Automatic Pressure Controller) valve 243 and a vacuum pump 246 serving as a vacuum exhaust apparatus are sequentially connected to the exhaust pipe 231 in this order from an upstream side to a downstream side of the exhaust pipe 231. With the vacuum pump 246 in operation, the APC valve 243 may be opened or closed to perform a vacuum exhaust of the process chamber 201a or stop the vacuum exhaust of the process chamber 201a. Further, with the vacuum pump 246 in operation, an opening degree of the APC valve 243 may be adjusted in order to adjust the inner pressure of the process chamber 201a. An exhauster (which is an exhaust structure or an exhaust system) (that is, an exhaust line) is constituted mainly by the exhaust hole 204a, the exhaust path 206, the exhaust pipe 231, the APC valve 243 and the pressure sensor 245. The exhauster may further include the vacuum pump 246.

A seal cap 219 serving as a furnace opening lid capable of airtightly sealing a lower end opening of the manifold 209 is provided under the manifold 209. The seal cap 219 is in contact with the lower end of the manifold 209 from thereunder. For example, the seal cap 219 is made of a metal such as SUS, and is of a disk shape. An O-ring 220b serving as a seal is provided on an upper surface of the seal cap 219 so as to be in contact with the lower end of the manifold 209. A rotator 267 configured to rotate the boat 217 accommodating the wafers 200 is provided at the seal cap 219 in a manner opposite to the process chamber 201a. A rotating shaft 255 of the rotator 267 is connected to the boat 217 through the seal cap 219. As the rotator 267 rotates the boat 217, the wafers 200 are rotated. The seal cap 219 may be elevated or lowered in the vertical direction by a boat elevator 115 serving as an elevating structure vertically provided outside the outer tube 203. When the seal cap 219 is elevated or lowered in the vertical direction by the boat elevator 115, the boat 217 may be transferred (loaded) into the process chamber 201a or transferred (unloaded) out of the process chamber 201a. The boat elevator 115 serves as a transfer device (which is a transfer structure or a transfer system) that loads the boat 217 and the wafers 200 accommodated in the boat 217 into the process chamber 201a or unloads the boat 217 and the wafers 200 accommodated in the boat 217 out of the process chamber 201a.

The boat 217 serving as a substrate retainer is configured to accommodate (or support) the wafers 200 (for example, 25 to 200 wafers) while the wafers 200 are horizontally oriented with their centers aligned with one another with a predetermined interval therebetween in a multistage manner. For example, the boat 217 is made of a heat resistant material such as quartz and SiC. A plurality of heat insulating plates 218 horizontally oriented are provided under the boat 217 in a multistage manner (now shown). Each of the heat insulating plates 218 is made of a heat resistant material such as quartz and SiC. With such a configuration, the heat insulating plates 218 suppress the transmission of the heat from the heater 207 to the seal cap 219. However, the present embodiments are not limited thereto. For example, instead of the heat insulating plates 218, a heat insulating cylinder (not shown) such as a cylinder made of a heat resistant material such as quartz and SiC may be provided under the boat 217.

As shown in FIG. 2, a temperature sensor 263 serving as a temperature detector is installed in the inner tube 204. An amount of the current supplied (or applied) to the heater 207 is adjusted based on temperature information detected by the temperature sensor 263 such that a desired temperature distribution of an inner temperature of the process chamber 201a can be obtained. Similar to the nozzles 410, 420 and 430, the temperature sensor 263 is L-shaped, and is provided along the inner wall of the inner tube 204.

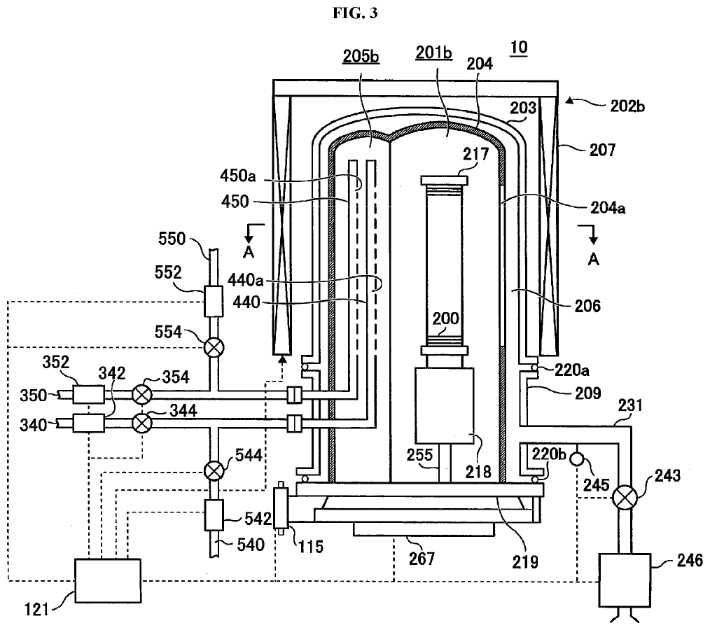

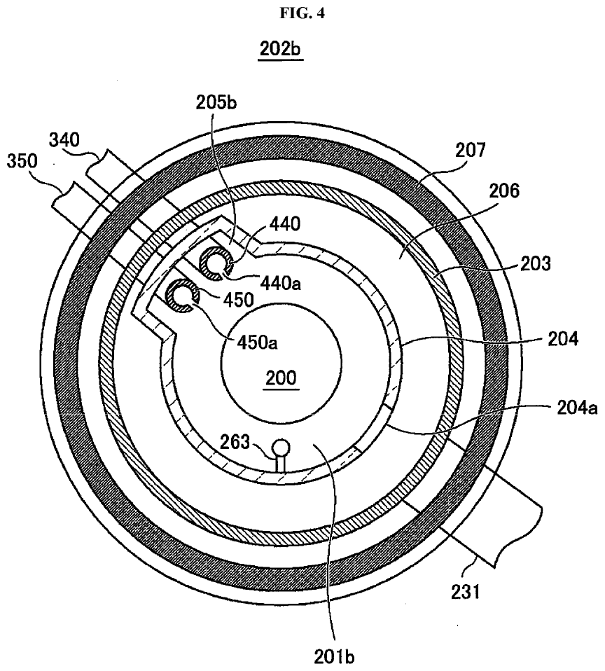

FIG. 3 is a diagram schematically illustrating a vertical cross-section of a process furnace 202b serving as the second process structure provided in the substrate processing apparatus 10, and FIG. 4 is a diagram schematically illustrating a horizontal cross-section, taken along a line A-A shown in FIG. 3, of the process furnace 202b of the substrate processing apparatus 10. Configurations in a process chamber 201b of the process furnace 202b in the present embodiments differ from those in the process chamber 201a of the process furnace 202a described above. In the following descriptions, portions of the process furnace 202b different from those of the process furnace 202a will be mainly described below, and descriptions of the same portions of the process furnace 202b and the process furnace 202a will be omitted. That is, the same components as those of the process furnace 202a will be denoted by like reference numerals, and detailed description thereof will be omitted. The process furnace 202b is provided with the process chamber 201b serving as a second process chamber.

Nozzles 440 and 450 are installed in the process chamber 201b so as to penetrate the side wall of the manifold 209 and the inner tube 204. Gas supply pipes 340 and 350 are connected to the nozzles 440 and 450, respectively. However, the process furnace 202b of the present embodiments is not limited to an exemplary configuration described above.

Mass flow controllers (MFCs) 342 and 352 and valves 344 and 354 are sequentially installed at the gas supply pipes 340 and 350 in this order from upstream sides to downstream sides of the gas supply pipes 340 and 350 in the gas flow direction, respectively. Gas supply pipes 540 and 550 through which the inert gas is supplied are connected to the gas supply pipes 340 and 350 at downstream sides of the valves 344 and 354, respectively. MFCs 542 and 552 and valves 544 and 554 are sequentially installed at the gas supply pipes 540 and 550 in this order from upstream sides to downstream sides of the gas supply pipes 540 and 550 in the gas flow direction, respectively.

The nozzles 440 and 450 are connected to front ends (tips) of the gas supply pipes 340 and 350, respectively. Each of the nozzles 440 and 450 may be configured as an L-shaped nozzle. Horizontal portions of the nozzles 440 and 450 are installed so as to penetrate the side wall of the manifold 209 and the inner tube 204. Vertical portions of the nozzles 440 and 450 are installed in a spare chamber (which is a preliminary chamber) 205b of a channel shape (a groove shape) protruding outward in the radial direction of the inner tube 204 and extending in the vertical direction. That is, the vertical portions of the nozzles 440 and 450 are installed in the spare chamber 205b toward the upper end of the inner tube 204 (in the direction in which the wafers 200 are arranged) and along the inner wall of the inner tube 204.

The nozzles 440 and 450 extend from a lower region of the process chamber 201b to an upper region of the process chamber 201b. The nozzles 440 and 450 are provided with a plurality of gas supply holes 440a and a plurality of gas supply holes 450a, respectively, at positions facing the wafers 200.

The gas supply holes 440a of the nozzle 440 and the gas supply holes 450a of the nozzle 450 are provided from the lower portion to the upper portion of the boat 217 described later. Therefore, the process gas supplied into the process chamber 201b through the gas supply holes 440a of the nozzle 440 and the gas supply holes 450a of the nozzle 450 is supplied onto the wafers 200 accommodated in the boat 217 from the lower portion to the upper portion thereof, that is, the entirety of the wafers 200 accommodated in the boat 217.

A gas containing a second metal element (hereinafter, also referred to as a “second metal-containing gas”) serving as one of the process gases is supplied into the process chamber 201b through the gas supply pipe 340 provided with the MFC 342 and the valve 344 and the nozzle 440.

A first reactive gas (which reacts with the second metal-containing gas) serving as one of the process gases is supplied into the process chamber 201b through the gas supply pipe 350 provided with the MFC 352 and the valve 354 and the nozzle 450.

For example, as the inert gas, the nitrogen gas (N2 gas) is supplied into the process chamber 201b through the gas supply pipes 540 and 550 provided with the MFCs 542 and 552 and the valves 544 and 554, respectively, and the nozzles 440 and 450. While the present embodiments will be described by way of an example in which the N₂ gas is used as the inert gas for the process chamber 201b, the inert gas for the process chamber 201b according to the present embodiments is not limited thereto. For example, instead of the N₂ gas or in addition to the N2 gas, the rare gas such as argon (Ar) gas, helium (He) gas, neon (Ne) gas and xenon (Xe) gas may be used as the inert gas for the process chamber 201b.

A process gas supplier (which is a process gas supply structure or a process gas supply system) for the process chamber 201b is constituted mainly by the gas supply pipes 340 and 350, the MFCs 342 and 352, the valves 344 and 354 and the nozzles 440 and 450. However, it is also possible for the nozzles 440 and 450 alone to be referred to as the process gas supplier for the process chamber 201b. The process gas supplier for the process chamber 201b may also be simply referred to as a “gas supplier” (which is a gas supply structure or a gas supply system) for the process chamber 201b. When the second metal-containing gas is supplied through the gas supply pipe 340, a second metal-containing gas supplier (which is a second metal-containing gas supply structure or a second metal-containing gas supply system) is constituted mainly by the gas supply pipe 340, the MFC 342 and the valve 344. The second metal-containing gas supplier may further include the nozzle 440. Further, when the first reactive gas is supplied through the gas supply pipe 350, a first reactive gas supplier (which is a first reactive gas supply structure or a first reactive gas supply system) is constituted mainly by the gas supply pipe 350, the MFC 352 and the valve 354. The first reactive gas supplier may further include the nozzle 450. The first reactive gas supplier may also be referred to as a “reducing gas supplier” (which is a reducing gas supply structure or a reducing gas supply system). When a hydrogen-containing gas serving as the first reactive gas is supplied through the gas supply pipe 350, the first reactive gas supplier may also be referred to as a “hydrogen-containing gas supplier” which is a hydrogen-containing gas supply structure or a hydrogen-containing gas supply system. In addition, an inert gas supplier (which is an inert gas supply structure or an inert gas supply system) for the process chamber 201b is constituted mainly by the gas supply pipes 540 and 550, the MFCs 542 and 552 and the valves 544 and 554. The inert gas supplier for the process chamber 201b may also be referred to as a “purge gas supplier” (which is a purge gas supply structure or a purge gas supply system), a “dilution gas supplier” (which is a dilution gas supply structure or a dilution gas supply system) or a “carrier gas supplier” (which is a carrier gas supply structure or a carrier gas supply system).

### <Configuration of Controller>

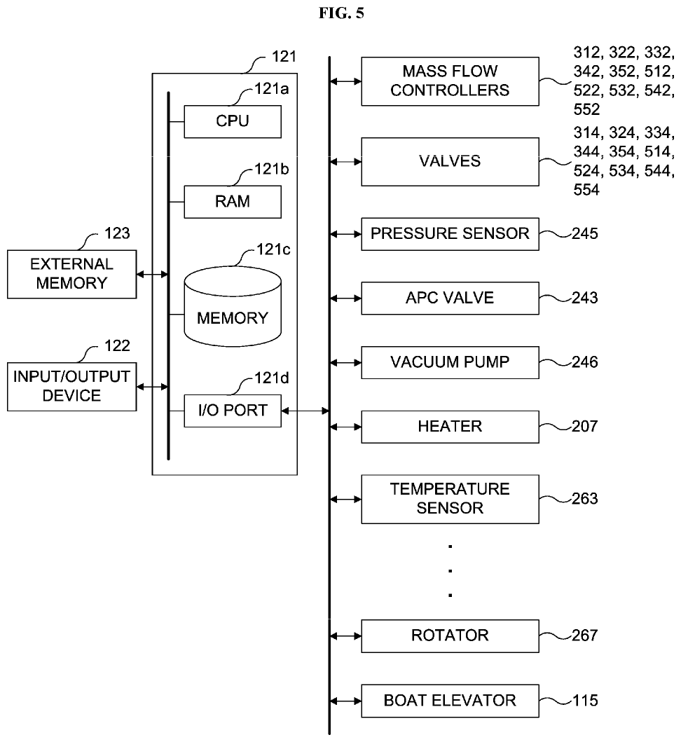

As shown in FIG. 5, a controller 121 serving as a control structure (or a control system) is constituted by a computer including a CPU (Central Processing Unit) 121a, a RAM (Random Access Memory) 121b, a memory 121c and an I/O (input/output) port 121d. The RAM 121b, the memory 121c and the I/O port 121d may exchange data with the CPU 121a through an internal bus (not shown). For example, an input/output device 122 constituted by a component such as a touch panel is connected to the controller 121.

The memory 121c is configured by a component such as a flash memory and a hard disk drive (HDD). For example, a control program configured to control an operation of the substrate processing apparatus 10 or a process recipe containing information on sequences and conditions of the method of manufacturing the semiconductor device described later is readably stored in the memory 121c. The process recipe is obtained by combining steps of the method of manufacturing the semiconductor device described later such that the controller 121 can execute the steps to acquire a predetermined result, and functions as a program. Hereafter, the process recipe and the control program may be collectively or individually referred to as a “program”. In the present specification, the term “program” may refer to the process recipe alone, may refer to the control program alone, or may refer to a combination of the process recipe and the control program. The RAM 121b functions as a memory area (work area) where a program or data read by the CPU 121a is temporarily stored.

The I/O port 121d is connected to the components of the process furnaces 202a and 202b described above such as the MFCs 312, 322, 332, 342, 352, 512, 522, 532, 542 and 552, the valves 314, 324, 334, 344, 354, 514, 524, 534, 544 and 554, the pressure sensor 245, the APC valve 243, the vacuum pump 246, the heater 207, the temperature sensor 263, the rotator 267 and the boat elevator 115.

The CPU 121a is configured to read the control program from the memory 121c and execute the read control program. In addition, the CPU 121a is configured to read a recipe such as the process recipe from the memory 121c in accordance with an operation command inputted from the input/output device 122. In accordance with the contents of the read recipe, the CPU 121a may be configured to control various operations such as flow rate adjusting operations for various gases by the MFCs 312, 322, 332, 342, 352, 512, 522, 532, 542 and 552, opening and closing operations of the valves 314, 324, 334, 344, 354, 514, 524, 534, 544 and 554, an opening and closing operation of the APC valve 243, a pressure adjusting operation by the APC valve 243 based on the pressure sensor 245, a temperature adjusting operation by the heater 207 based on the temperature sensor 263, a start and stop of the vacuum pump 246, an operation of adjusting a rotation and a rotation speed of the boat 217 by the rotator 267, an elevating and lowering operation of the boat 217 by the boat elevator 115 and an operation of transferring and accommodating the wafer 200 into the boat 217.

The controller 121 may be embodied by installing the above-described program stored in an external memory 123 into the computer. For example, the external memory 123 may include a magnetic tape, a magnetic disk such as a flexible disk and a hard disk, an optical disk such as a CD and a DVD, a magneto-optical disk such as an MO and a semiconductor memory such as a USB memory and a memory card. The memory 121c or the external memory 123 may be embodied by a non-transitory computer readable recording medium. Hereafter, the memory 121c and the external memory 123 are collectively or individually referred to as a “recording medium”. In the present specification, the term “recording medium” may refer to the memory 121c alone, may refer to the external memory 123 alone, and may refer to both of the memory 121c and the external memory 123. Instead of the external memory 123, a communication structure such as the Internet and a dedicated line may be used for providing the program to the computer.

### (2) Substrate Processing

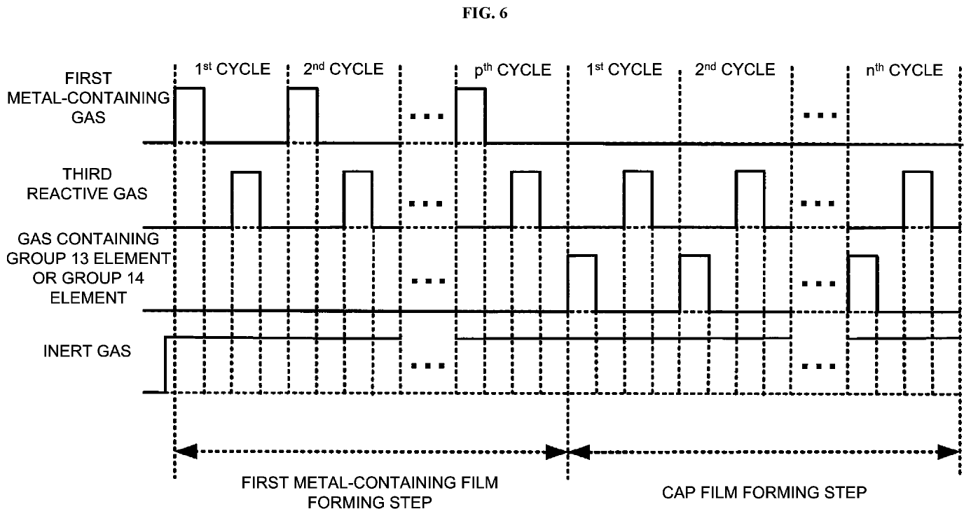

Hereinafter, as a part of the manufacturing process of the semiconductor device, an exemplary sequence of a process (substrate processing) will be described by way of the example in which, after forming the first metal-containing film containing the first metal element on the wafer 200 and the cap film on the first metal-containing film in the process furnace 202a, the second metal-containing film containing the second metal element is formed on the wafer 200 in the process furnace 202b while removing at least part of the cap film formed on the first metal-containing film. The substrate processing will be described with reference to FIGS. 6, 7, 8A, 8B and 8C. In the following description, operations of the components constituting the substrate processing apparatus 10 are controlled by the controller 121.

The substrate processing (that is, the manufacturing process of the semiconductor device) according to the present embodiments may include: (A) preparing the substrate (that is, the wafer 200) including a film containing the first metal element (that is, the first metal-containing film) and a film containing the Group 13 element or the Group 14 element (that is, the cap film) formed on the film containing the first metal element; and (B) forming a film containing the second metal element (that is, the second metal-containing film) on the substrate while removing at least part of the film containing the Group 13 element or the Group 14 element formed on the film containing the first metal element by performing: (a) supplying the gas containing the second metal element (that is, the second metal-containing gas) to the substrate; and (b) supplying the first reactive gas to the substrate.

In the present specification, the term “wafer” may refer to “a wafer itself”, or may refer to “a wafer and a stacked structure (aggregated structure) of a predetermined layer (or layers) or a film (or films) formed on a surface of the wafer”. That is, the term “wafer” may collectively refer to the wafer and the layer (or layers) or the film (or films) formed on the surface of the wafer. In the present specification, the term “a surface of a wafer” may refer to “a surface (exposed surface) of a wafer itself”, or may refer to “a surface of a predetermined layer or a film formed on a wafer, i.e. a top surface (uppermost surface) of the wafer as a stacked structure”. In the present specification, the terms “substrate” and “wafer” may be used as substantially the same meaning.

### A. Process of Forming First Metal-Containing Film

First, the wafers 200 are transferred (loaded) into the process furnace 202a serving as the first process structure, and then, the first metal-containing film containing the first metal element and the cap film containing the Group 13 element or the Group 14 element are formed on the wafer 200.

### <Wafer Charging Step and Boat Loading Step>

The wafers 200 are charged (transferred) into the boat 217 (wafer charging step). After the boat 217 is charged with the wafers 200, as shown in FIG. 1, the boat 217 charged with the wafers 200 is elevated by the boat elevator 115 and loaded (transferred) into the process chamber 201a (boat loading step). With the boat 217 loaded, the seal cap 219 seals a lower end opening of the outer tube 203 (that is, the lower end opening of the manifold 209) via the O-ring 220b.

### <Pressure Adjusting Step and Temperature Adjusting Step>

The vacuum pump 246 vacuum-exhausts the inner atmosphere of the process chamber 201a such that the inner pressure of the process chamber 201a (that is, a pressure in a space in which the wafers 200 are accommodated) reaches and is maintained at a desired pressure (vacuum degree). Meanwhile, the inner pressure of the process chamber 201a is measured by the pressure sensor 245, and the APC valve 243 is feedback-controlled based on the pressure information measured by the pressure sensor 245 (pressure adjusting step). In addition, the heater 207 heats the process chamber 201a such that the inner temperature of the process chamber 201a reaches and is maintained at a desired temperature. Meanwhile, the amount of the current supplied to the heater 207 is feedback-controlled based on the temperature information detected by the temperature sensor 263 such that the desired temperature distribution of the inner temperature of the process chamber 201a is obtained (temperature adjusting step). The rotator 267 starts rotating the wafer 200. The vacuum pump 246 continuously vacuum-exhausts the inner atmosphere of the process chamber 201a, the heater 207 continuously heats the process chamber 201a and the rotator 267 continuously rotates the wafer 200 until at least a processing of the wafer 200 is completed.

### <First Metal-Containing Film Forming Step>

Subsequently, a first metal-containing film forming step is performed by performing steps S10 through S14 described below.

### <First Metal-Containing Gas Supply Step S10>

The valve 314 is opened to supply the first metal-containing gas into the gas supply pipe 310. A flow rate of the first metal-containing gas supplied into the gas supply pipe 310 is adjusted by the MFC 312. The first metal-containing gas whose flow rate is adjusted is then supplied into the process chamber 201a through the gas supply holes 410a of the nozzle 410, and is exhausted through the exhaust pipe 231. In the present step, simultaneously with a supply of the first metal-containing gas, the valve 514 is opened to supply the inert gas such as the N2 gas into the gas supply pipe 510. A flow rate of the inert gas supplied into the gas supply pipe 510 is adjusted by the MFC 512. The inert gas whose flow rate is adjusted is then supplied into the process chamber 201a together with the first metal-containing gas, and is exhausted through the exhaust pipe 231. In the present step, in order to prevent the first metal-containing gas from entering the nozzles 420 and 430, the valves 524 and 534 may be opened to supply the inert gas into the gas supply pipes 520 and 530. The inert gas is then supplied into the process chamber 201a through the gas supply pipes 320 and 330 and the nozzles 420 and 430, and is exhausted through the exhaust pipe 231.

In the present step, for example, the APC valve 243 is appropriately adjusted (or controlled) such that the inner pressure of the process chamber 201a is set to a pressure within a range from 1 Pa to 3,990 Pa. For example, a supply flow rate of the first metal-containing gas controlled by the MFC 312 is set to a flow rate within a range from 0.1 slm to 2.0 slm. For example, a supply flow rate of the inert gas controlled by each of the MFCs 512, 522 and 532 is set to a flow rate within a range from 0.1 slm to 20 slm. In the following, for example, the temperature of the heater 207 is set such that the temperature of the wafer 200 reaches and is maintained at a temperature within a range from 300° C. to 650° C. For example, a supply time (which is a time duration) of supplying the first metal-containing gas to the wafer 200 is set to a time duration within a range from 0.01 second to 30 seconds. In the present specification, a notation of a numerical range such as “from 1 Pa to 3,990 Pa” means that a lower limit and an upper limit are included in the numerical range. Therefore, for example, the numerical range “from 1 Pa to 3,990 Pa” means a range equal to or higher than 1 Pa and equal to or lower than 3,990 Pa. The same also applies to other numerical ranges described in the present specification.

In the present step, the first metal-containing gas is supplied to the wafer 200. In the present step, for example, as the first metal-containing gas, a gas containing titanium (Ti) as the first metal element may be used. For example, a gas such as titanium tetrachloride (TiCl4) gas containing a halogen element may be used as the gas containing titanium.

### <Purge Step S11>

After a predetermined time has elapsed from the supply of the first metal-containing gas, the valve 314 is closed to stop the supply of the first metal-containing gas. In the present step, with the APC valve 243 of the exhaust pipe 231 open, the vacuum pump 246 vacuum-exhausts the inner atmosphere of the process chamber 201a to remove a residual gas remaining in the process chamber 201a such as a residual first metal-containing gas which did not react or which contributed to a formation of the first metal-containing film from the process chamber 201a. In the present step, by maintaining the valves 514, 524 and 534 open, the inert gas is continuously supplied into the process chamber 201a. The inert gas serves as a purge gas, which improves an efficiency of removing the residual gas remaining in the process chamber 201a such as the residual first metal-containing gas which did not react or which contributed to the formation of the first metal-containing film out of the process chamber 201a.

### <Third Reactive Gas Supply Step S12>

After a predetermined time has elapsed from a start of the purge step S11, the valve 324 is opened to supply the third reactive gas into the gas supply pipe 320. A flow rate of the third reactive gas supplied into the gas supply pipe 320 is adjusted by the MFC 322. The third reactive gas whose flow rate is adjusted is then supplied into the process chamber 201a through the gas supply holes 420a of the nozzle 420, and is exhausted through the exhaust pipe 231. In the present step, simultaneously with a supply of the third reactive gas, the valve 524 is opened to supply the inert gas into the gas supply pipe 520. In the present step, in order to prevent the third reactive gas from entering the nozzles 410 and 430, the valves 514 and 534 may be opened to supply the inert gas into the gas supply pipes 510 and 530.

In the present step, for example, the APC valve 243 is appropriately adjusted (or controlled) such that the inner pressure of the process chamber 201a is set to a pressure within a range from 1 Pa to 3,990 Pa. For example, a supply flow rate of the third reactive gas controlled by the MFC 322 is set to a flow rate within a range from 0.1 slm to 30 slm. For example, a supply flow rate of the inert gas controlled by each of the MFCs 512, 522 and 532 is set to a flow rate within a range from 0.1 slm to 20 slm. For example, a supply time (which is a time duration) of supplying the third reactive gas to the wafer 200 is set to a time duration within a range from 0.01 second to 30 seconds.

In the present step, the third reactive gas is supplied to the wafer 200. In the present step, for example, as the third reactive gas, the nitrogen-containing gas containing nitrogen may be used. For example, a gas such as ammonia (NH3) gas may be used as the nitrogen-containing gas.

### <Purge Step S13>

After a predetermined time has elapsed from the supply of the third reactive gas, the valve 324 is closed to stop the supply of the third reactive gas. Then, a residual gas remaining in the process chamber 201a such as a residual third reactive gas which did not react or which contributed to the formation of the first metal-containing film is removed out of the process chamber 201a in substantially the same manners as in the purge step S11 described above.

### <Performing a Predetermined Number of Times S14>

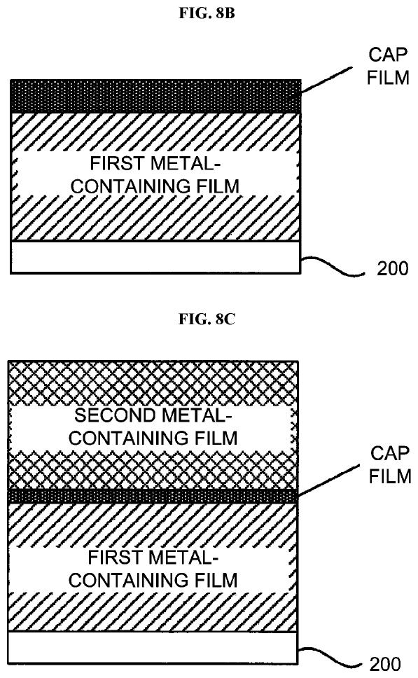

By performing a cycle (in which the step S10 through the step S13 described above are sequentially performed in this order) at least once (that is, a predetermined number of times (p times)), the first metal-containing film of a predetermined thickness is formed on the wafer 200 as shown in FIG. 8A. It is preferable that the cycle described above is repeatedly performed a plurality number of times. According to the present embodiments, for example, a titanium nitride (TiN) film is formed on the wafer 200 as the first metal-containing film.

### <Cap Film Forming Step>

Subsequently, a cap film forming step of forming the cap film on the wafer 200 where the first metal-containing film is formed on the surface thereof is performed by performing steps S20 through S24 described below. The cap film is a film containing the Group 13 element or the Group 14 element. The cap film functions as an anti-oxidation film capable of preventing an oxidation of an outermost surface of the first metal-containing film described above.

### <Gas Containing Group 13 Element or Group 14 Element Supply Step S20>

The valve 334 is opened to supply the gas containing the Group 13 element or the Group 14 element into the gas supply pipe 330. A flow rate of the gas containing the Group 13 element or the Group 14 element supplied into the gas supply pipe 330 is adjusted by the MFC 332. The gas containing the Group 13 element or the Group 14 element whose flow rate is adjusted is then supplied into the process chamber 201a through the gas supply holes 430a of the nozzle 430, and is exhausted through the exhaust pipe 231. In the present step, simultaneously with a supply of the gas containing the Group 13 element or the Group 14 element, the valve 534 is opened to supply the inert gas into the gas supply pipe 530. In the present step, in order to prevent the gas containing the Group 13 element or the Group 14 element from entering the nozzles 410 and 420, the valves 514 and 524 may be opened to supply the inert gas into the gas supply pipes 510 and 520.

In the present step, for example, the APC valve 243 is appropriately adjusted (or controlled) such that the inner pressure of the process chamber 201a is set to a pressure within a range from 1 Pa to 3,990 Pa. For example, a supply flow rate of the gas containing the Group 13 element or the Group 14 element controlled by the MFC 332 is set to a flow rate within a range from 0.1 slm to 30 slm. For example, a supply flow rate of the inert gas controlled by each of the MFCs 512, 522 and 532 is set to a flow rate within a range from 0.1 slm to 20 slm. For example, a supply time (which is a time duration) of supplying the gas containing the Group 13 element or the Group 14 element to the wafer 200 is set to a time duration within a range from 0.01 second to 30 seconds.

In the present step, the gas containing the Group 13 element or the Group 14 element is supplied to the wafer 200 with the first metal-containing film formed thereon. In the present step, for example, as the gas containing the Group 13 element or the Group 14 element, a silicon-containing gas containing silicon (Si) may be used. For example, a gas such as dichlorosilane (SiH2Cl2, abbreviated as DCS) gas may be used as the silicon-containing gas. By using the gas containing the Group 13 element or the Group 14 element, it is possible to easily sublimate and remove the cap film when forming the second metal-containing film described later.

For example, the group 14 element refers to one or more elements such as silicon (Si) and germanium (Ge). For example, as a gas containing the Group 14 element, a gas containing the one or more elements described above and at least one selected from the group consisting of hydrogen (H), a halogen element (such as fluorine (F) and chlorine (Cl)) and an alkyl group (for example, a methyl group (CH3)). For example, as the silicon-containing gas, a gas such as a silane-based gas and a halosilane-based gas may be used. For example, as the silane-based gas, a gas such as monosilane (SiH4) gas, disilane (Si2H6) gas and trisilane (Si3H8) gas may be used. For example, as the halosilane-based gas, a gas such as dichlorosilane (SiH2Cl2) gas, trichlorosilane (SiHCl3) gas, tetrachlorosilane (SiCl4) gas and hexachlorodisilane (Si2Cl6) gas may be used.

### <Purge Step S21>

After a predetermined time has elapsed from the supply of the gas containing the Group 13 element or the Group 14 element, the valve 334 is closed to stop the supply of the gas containing the Group 13 element or the Group 14 element. Then, a residual gas remaining in the process chamber 201a such as a residual gas containing the Group 13 element or the Group 14 element which did not react or which contributed to a formation of the cap film is removed out of the process chamber 201a in substantially the same manners as in the purge step S11 described above.

### <Third Reactive Gas Supply Step S22>

After a predetermined time has elapsed from a start of the purge step S21, the valve 324 is opened to supply the third reactive gas into the gas supply pipe 320. The flow rate of the third reactive gas supplied into the gas supply pipe 320 is adjusted by the MFC 322. The third reactive gas whose flow rate is adjusted is then supplied into the process chamber 201a through the gas supply holes 420a of the nozzle 420, and is exhausted through the exhaust pipe 231. In the present step, simultaneously with the supply of the third reactive gas, the valve 524 is opened to supply the inert gas into the gas supply pipe 520. In the present step, in order to prevent the third reactive gas from entering the nozzles 410 and 430, the valves 514 and 534 may be opened to supply the inert gas into the gas supply pipes 510 and 530.

In the present step, for example, the APC valve 243 is appropriately adjusted (or controlled) such that the inner pressure of the process chamber 201a is set to a pressure within a range from 1 Pa to 3,990 Pa. For example, the supply flow rate of the third reactive gas controlled by the MFC 322 is set to a flow rate within a range from 0.1 slm to 30 slm. For example, the supply flow rate of the inert gas controlled by each of the MFCs 512, 522 and 532 is set to a flow rate within a range from 0.1 slm to 20 slm. For example, the supply time (which is the time duration) of supplying the third reactive gas to the wafer 200 is set to a time duration within a range from 0.01 second to 30 seconds.

In the present step, the third reactive gas is supplied to the wafer 200. In the present step, for example, as the third reactive gas, ammonia (NH3) gas serving as the nitrogen-containing gas containing nitrogen may be used.

### <Purge Step S23>

After a predetermined time has elapsed from the supply of the third reactive gas, the valve 324 is closed to stop the supply of the third reactive gas. Then, a residual gas remaining in the process chamber 201a such as a residual third reactive gas which did not react or which contributed to the formation of the cap film is removed out of the process chamber 201a in substantially the same manners as in the purge step S11 described above.

### <Performing a Predetermined Number of Times S24>

By performing a cycle (in which the step S20 through the step S23 described above are sequentially performed in this order) at least once (that is, a predetermined number of times (n times)), the cap film of a predetermined thickness is formed on the wafer 200 where the first metal-containing film is formed on the surface of the wafer 200, as shown in FIG. 8B. It is preferable that the cycle described above is repeatedly performed a plurality number of times. That is, the cycle is cyclically performed. Preferably, the thickness of the cap film formed in the present step is set to a thickness within a range from 0.2 nm to 3 nm. When the thickness of the cap film is thicker than 3 nm, the cap film may remain unremoved even after a second metal-containing film forming step described later is performed. When the thickness is less than 0.2 nm, the first metal-containing film provided under the cap film may be oxidized. That is, when the first metal-containing film is oxidized, the first metal-containing film may be etched during the second metal-containing film forming step. As a result, a deterioration of film properties of the first metal-containing film may occur. In the present specification, the “deterioration of the film properties of the first metal-containing film” may refer to a deterioration of a barrier performance when the first metal-containing film serves as a barrier film. Therefore, it is preferable to form the cap film with a thickness of 0.2 nm or more such that an oxidation of the first metal-containing film can be suppressed. By increasing the thickness of the cap film, an effect of suppressing the oxidation of the first metal-containing film also increases. However, the cap film may not be removed when forming the second metal-containing film. Therefore, in the present step, the cap film whose thickness is within a range from 0.2 nm to 3 nm, preferably from 0.2 nm to 2 nm is formed on the wafer 200 where the first metal-containing film is formed on the surface of the wafer 200. By setting the thickness to 2 nm or less, it is possible to remove the cap film during the second metal-containing film forming step. In the present step, for example, as the cap film, a silicon nitride (SiN) film (which is a film containing silicon as the Group 14 element) is formed. In the present specification, the thickness of 0.2 nm is a thickness of one atomic layer when the cap film is made of silicon nitride. Since the thickness of one atomic layer changes depending on a type of the cap film, the thickness (number of layers) of the cap film may be changed depending on the type of the cap film. By forming the cap film such that the thickness thereof corresponds to one atomic layer of a material constituting the cap film, it is possible to obtain the effect of suppressing the oxidation of the first metal-containing film. When the thickness of the cap film is less than the one atomic layer, holes will be formed. As a result, the effect of suppressing the oxidation of the first metal-containing film may be insufficient. Further, by setting the thickness of the cap film to about several atomic layers, it is possible to further obtain the effect of suppressing the oxidation of the first metal-containing film. In addition, when the thickness of the cap film is equal to the one atomic layer, a pinhole or the like may be formed. As a result, the first metal-containing film may be oxidized through the pinhole. Therefore, it is preferable that the thickness of the cap film is set to two atomic layers or more and several atomic layers or less. By forming the cap film whose thickness is two atomic layers or more, it is possible to suppress a formation of the pinhole. The pinhole may be caused by, for example, a steric hindrance caused by a molecular size of a source gas used for forming the cap film, reaction characteristics of the source gas or reaction characteristics of the reactive gas. Further, by setting the thickness of the cap film to several atomic layers, it is possible to form the second metal-containing film while removing at least part of the cap film formed on the first metal-containing film during the second metal-containing film forming step. For example, when the SiN film is formed as the cap film, the thickness (of the cap film) of two atomic layers to several atomic layers is from 0.4 nm to 1.8 nm. By setting the thickness (of the cap film) to 1.8 nm or less, it is possible to remove the cap film at an initial stage of the second metal-containing film forming step, and it is also possible to reduce a layer in which the second metal-containing film and the cap film are mixed with each other. In the layer in which the second metal-containing film and the cap film are mixed with each other, electrical properties of the second metal-containing film may deteriorate.

### <After-Purge Step and Returning to Atmospheric Pressure Step>

The inert gas is supplied into the process chamber 201a through each of the gas supply pipes 510, 520 and 530, and is exhausted through the exhaust pipe 231. The inert gas serves as the purge gas, so that the inner atmosphere of the process chamber 201a is purged with the inert gas. Thus, the residual gas remaining in the process chamber 201a or reaction by-products remaining in the process chamber 201a is removed from the process chamber 201a (after-purge step). Thereafter, the inner atmosphere of the process chamber 201a is replaced with the inert gas (substitution by inert gas), and the inner pressure of the process chamber 201a is returned to a normal pressure (atmospheric pressure) (returning to atmospheric pressure step).

### <Boat Unloading Step and Wafer Discharging Step>

Thereafter, the seal cap 219 is lowered by the boat elevator 115 and the lower end opening of the outer tube 203 (that is, the lower end opening of the manifold 209) is opened. The boat 217 with processed wafers 200 (where the first metal-containing film is formed on each of the wafers 200 and the cap film is formed on the first metal-containing film) charged therein is unloaded out of the outer tube 203 through the lower end opening of the outer tube 203 (boat unloading step). Then, the processed wafers 200 are discharged (transferred) out of the boat 217 (wafer discharging step).

### B. Process of Forming Second Metal-Containing Film

Subsequently, the wafers 200 processed in the process furnace 202a are transferred (loaded) into the process furnace 202b serving as the second process structure. That is, the wafer 200 (where the first metal-containing film is formed on the wafer 200 and the cap film is formed on the first metal-containing film) is prepared in the process furnace 202b. Then, an inner pressure of the process chamber 201b and a temperature distribution of an inner temperature of the process chamber 201b are adjusted to a desired pressure and a desired temperature distribution, respectively, by performing a pressure adjusting step and a temperature adjusting step (which are substantially the same as the pressure adjusting step and the temperature adjusting step, respectively, performed in the process furnace 202a). In addition, gas supply steps preformed in the process furnace 202b are different from those preformed in the process furnace 202a. Therefore, steps (which are performed in the process furnace 202b) different from those (which are performed in the process furnace 202a) will be mainly described below, and descriptions of steps (which are performed in the process furnace 202b) substantially the same as those (which are performed in the process furnace 202a) will be omitted.

### <Second Metal-Containing Film Forming Step>

Subsequently, the second metal-containing film forming step of forming the second metal-containing film containing the second metal element on the wafer 200 with the cap film formed on the surface thereof while removing at least part of the cap film formed on the first metal-containing film is performed by performing steps S30 through S34 described below.

### <Second Metal-Containing Gas Supply Step S30>

The valve 344 is opened to supply the second metal-containing gas into the gas supply pipe 340. A flow rate of the second metal-containing gas supplied into the gas supply pipe 340 is adjusted by the MFC 342. The second metal-containing gas whose flow rate is adjusted is then supplied into the process chamber 201b through the gas supply holes 440a of the nozzle 440, and is exhausted through the exhaust pipe 231. In the present step, simultaneously with a supply of the second metal-containing gas, the valve 544 is opened to supply the inert gas such as the N2 gas into the gas supply pipe 540. A flow rate of the inert gas supplied into the gas supply pipe 540 is adjusted by the MFC 542. The inert gas whose flow rate is adjusted is then supplied into the process chamber 201b together with the second metal-containing gas, and is exhausted through the exhaust pipe 231. In the present step, in order to prevent the second metal-containing gas from entering the nozzle 450, the valve 554 may be opened to supply the inert gas into the gas supply pipe 550. The inert gas is then supplied into the process chamber 201b through the gas supply pipe 350 and the nozzle 450, and is exhausted through the exhaust pipe 231.

In the present step, for example, the APC valve 243 is appropriately adjusted (or controlled) such that the inner pressure of the process chamber 201b is set to a pressure within a range from 0.1 Pa to 6,650 Pa. For example, a supply flow rate of the second metal-containing gas controlled by the MFC 342 is set to a flow rate within a range from 0.01 slm to 10 slm. For example, a supply flow rate of the inert gas controlled by each of the MFCs 542 and 552 is set to a flow rate within a range from 0.1 slm to 20 slm. For example, a supply time (which is a time duration) of supplying the second metal-containing gas to the wafer 200 is set to a time duration within a range from 0.01 second to 30 seconds. In the present step, for example, the temperature of the heater 207 is set such that the temperature of the wafer 200 reaches and is maintained at a temperature within a range from 250° C. to 550° C. In the present step, the second metal-containing gas and the inert gas are supplied into the process chamber 201b without supplying other gases thereto. By supplying the second metal-containing gas, while removing the cap film on the wafer 200, for example, the second metal-containing film with a thickness of less than one atomic layer to several atomic layers is formed on the wafer 200 (that is, on a base film formed on the surface of the wafer 200).

In the present step, the second metal-containing gas is supplied to the wafer 200 with the cap film formed on the surface thereof. In the present step, for example, as the second metal-containing gas, a gas containing tungsten (W) as the second metal element and fluorine (F) as the halogen element, that is, a halogen-containing gas may be used. For example, tungsten hexafluoride (WF6) gas may be used as the gas containing tungsten (W) and fluorine (F).

In the present step, the cap film is sublimated by supplying the second metal-containing gas. That is, the cap film reacts with the halogen element contained in the second metal-containing gas to remove (or etch) the cap film. Specifically, by supplying the WF6 gas serving as an example of the second metal-containing gas to the SiN film serving as an example of the cap film, the SiN reacts with the WF6. Thereby, tungsten (W) is adsorbed on the surface of the wafer 200. As a result, silicon tetrafluoride (SiF4) and the N2 are generated. Since the SiF4 is easily sublimated, the SiF4 is sublimated and the N2 is removed by performing a purge step S31 described below. That is, the cap film is removed.

In the present specification, a state in which a part of the cap film remains may also be referred to as a state in which the cap film is removed. That is, a part of the cap film may remain in the second metal-containing film. In a device structure, for example, the TiN film may be formed on an aluminum oxide (AlO) film, and a tungsten (W) film may be formed thereon. In such a case, the W film functions as an electrode and the TiN film does not function as an electrode. Therefore, even when an insulating film exists between the W film and the TiN film, electrical properties of the W film and the TiN film are hardly affected.

### <Purge Step S31>

After a predetermined time has elapsed from the supply of the second metal-containing gas, the valve 344 is closed to stop the supply of the second metal-containing gas. In the present step, with the APC valve 243 of the exhaust pipe 231 open, the vacuum pump 246 vacuum-exhausts an inner atmosphere of the process chamber 201b to remove a residual gas remaining in the process chamber 201b such as a residual second metal-containing gas which did not react or which contributed to a removal of the cap film and a formation of the second metal-containing film from the process chamber 201b. In the present step, by maintaining the valves 544 and 554 open, the inert gas is continuously supplied into the process chamber 201b. The inert gas serves as the purge gas, which improves an efficiency of removing the residual gas remaining in the process chamber 201b such as the residual second metal-containing gas which did not react or which contributed to the removal of the cap film and the formation of the second metal-containing film out of the process chamber 201b.

### <First Reactive Gas Supply Step S32>

After a predetermined time has elapsed from a start of the purge step S31, the valve 354 is opened to supply the first reactive gas into the gas supply pipe 350. A flow rate of the first reactive gas supplied into the gas supply pipe 350 is adjusted by the MFC 352. The first reactive gas whose flow rate is adjusted is then supplied into the process chamber 201b through the gas supply holes 450a of the nozzle 450, and is exhausted through the exhaust pipe 231. In the present step, simultaneously with a supply of the first reactive gas, the valve 554 is opened to supply the inert gas into the gas supply pipe 550. The flow rate of the inert gas supplied into the gas supply pipe 550 is adjusted by the MFC 552. The inert gas whose flow rate is adjusted is then supplied into the process chamber 201b together with the first reactive gas, and is exhausted through the exhaust pipe 231. In the present step, in order to prevent the first reactive gas from entering the nozzle 440, the valve 544 may be opened to supply the inert gas into the gas supply pipe 540. The inert gas is then supplied into the process chamber 201b through the gas supply pipe 340 and the nozzle 440, and is exhausted through the exhaust pipe 231.

In the present step, for example, the APC valve 243 is appropriately adjusted (or controlled) such that the inner pressure of the process chamber 201b is set to a pressure within a range from 1 Pa to 3,990 Pa. For example, a supply flow rate of the first reactive gas controlled by the MFC 352 is set to a flow rate within a range from 0.1 slm to 50 slm. For example, a supply flow rate of the inert gas controlled by each of the MFCs 542 and 552 is set to a flow rate within a range from 0.1 slm to 20 slm. For example, a supply time (which is a time duration) of supplying the first reactive gas to the wafer 200 is set to a time duration within a range from 0.1 second to 20 seconds. In the present step, for example, the temperature of the heater 207 is set such that the temperature of the wafer 200 reaches and is maintained at a temperature within a range from 200° C. to 600° C. In the present step, the first reactive gas and the inert gas are supplied into the process chamber 201b without supplying other gases thereto. By supplying the first reactive gas, while removing the cap film on the wafer 200, for example, the second metal-containing film with the thickness of less than one atomic layer to several atomic layers is formed on the wafer 200 (that is, on the base film formed on the surface of the wafer 200).

In the present step, the first reactive gas is supplied to the wafer 200 with the cap film formed on the surface thereof. In the present step, for example, as the first reactive gas, a gas containing hydrogen (H) and serving as the reducing gas (hereinafter, also simply referred to as the “hydrogen-containing gas”) may be used. For example, hydrogen (H2) gas may be used as the hydrogen-containing gas.

By supplying the first reactive gas, the halogen element in the cap film is removed. That is, the cap film is further removed. Specifically, by supplying the WF6 gas serving as an example of the second metal-containing gas and the H2 gas serving as an example of the first reactive gas to the wafer 200 with the cap film formed on the surface thereof, the WF6 reacts with the H2. Thereby, hydrogen fluoride (HF) is generated. As a result, the tungsten (W) film from which fluorine (F) is removed is formed. Furthermore, the SiN film serving as the cap film is removed by the HF generated by the reaction described above. That is, the cap film is removed by the halogen element contained in the second metal-containing gas, and further the cap film is removed by the HF generated by supplying the second metal-containing gas and the first reactive gas.

That is, by forming the cap film on the first metal-containing film, it is possible to suppress the oxidation of the first metal-containing film. In addition, when the second metal-containing film is formed on the cap film, it is possible to remove the cap film by sublimating the cap film. That is, it is possible to form the second metal-containing film in which a content of the Group 13 element or the Group 14 element contained in the cap film is low.

In the present step, the supply flow rate of the first reactive gas is set to be smaller than the supply flow rate of the second metal-containing gas described above, and after a predetermined time (after a predetermined number of times), the supply flow rate of the first reactive gas is changed to substantially the same as the supply flow rate of the second metal-containing gas. In the present specification, when the supply flow rate of the first reactive gas is “substantially the same” as the supply flow rate of the second metal-containing gas, for example, the supply flow rate of the first reactive gas is 90% to 110% of the supply flow rate of the second metal-containing gas. Thus, by supplying the second metal-containing gas at a higher supply flow rate than the first reactive gas in the initial stage in a manner described above, it is possible to promote (or accelerate) the reaction between the halogen element contained in the second metal-containing gas and the cap film. Thereby, it is possible to remove the cap film. Then, after the cap film is removed after the predetermined time has elapsed, by setting (adjusting) the supply flow rate of the first reactive gas at substantially the same as the supply flow rate of the second metal-containing gas, it is possible to promote (or accelerate) the reaction between the first reactive gas and the second metal-containing gas. Thereby, it is possible to form the second metal-containing film in which a content of the halogen element is low. That is, it is possible to form the second metal-containing film (in which the content of the halogen element is low) on the first metal-containing film while suppressing the etching of the first metal-containing film due to the formation of the second metal-containing film.

For example, the supply flow rate of the first reactive gas may be set to be higher than the supply flow rate of the inert gas serving as the carrier gas in the initial stage, and after a predetermined time (after a predetermined number of times), the supply flow rate of the first reactive gas may be changed to be lower than the supply flow rate of the inert gas. By supplying the first reactive gas at a higher supply flow rate than the inert gas in the initial stage in a manner described above, it is possible to promote the reaction between the second metal-containing gas and the first reactive gas. Thereby, it is possible to generate a large amount of the HF, and it is also possible to remove the cap film. Then, after the cap film is removed after the predetermined time has elapsed, by setting (adjusting) the supply flow rate of the first reactive gas to be lower than the supply flow rate of the inert gas, it is possible to suppress a formation of the reaction by-products.

### <Purge Step S33>

After a predetermined time has elapsed from the supply of the first reactive gas, the valve 354 is closed to stop the supply of the first reactive gas. Then, a residual gas remaining in the process chamber 201b, such as a residual first reactive gas which did not react or which contributed to the removal of the cap film and the formation of the second metal-containing film, are removed out of the process chamber 201b in the same sequential order as the step S11.

### <Performing a Predetermined Number of Times S34>

By performing a cycle (in which the step S30 through the step S33 described above are sequentially performed in this order) at least once (that is, a predetermined number of times (m times)), it is possible to form the second metal-containing film (which contains the second metal element) of a predetermined thickness on the wafer 200 while sublimating the cap film formed on the wafer 200. That is, as shown in FIG. 8C, it is possible to form the second metal-containing film of the predetermined thickness on the wafer 200 while removing at least part of the cap film formed on the first metal-containing film. It is preferable that the cycle described above is repeatedly performed a plurality number of times. An execution number of the cycle (m times) in the second metal-containing film forming step is set to be greater than that of the cycle (n times) in the cap film forming step described above. That is, m is set to be greater than n (m and n are positive integers). Thereby, it is possible to form the second metal-containing film of the predetermined thickness on the wafer 200 while sublimating the cap film formed on the wafer 200.

### <After-Purge Step and Returning to Atmospheric Pressure Step>

The inert gas is supplied into the process chamber 201b through each of the gas supply pipes 540 and 550, and is exhausted through the exhaust pipe 231. The inert gas serves as the purge gas, so that the inner atmosphere of the process chamber 201b is purged with the inert gas. Thus, the residual gas remaining in the process chamber 201b or the reaction by-products remaining in the process chamber 201b is removed from the process chamber 201b (after-purge step). Thereafter, the inner atmosphere of the process chamber 201b is replaced with the inert gas (substitution by inert gas), and the inner pressure of the process chamber 201b is returned to the normal pressure (atmospheric pressure) (returning to atmospheric pressure step).

### <Boat Unloading Step and Wafer Discharging Step>

Thereafter, the seal cap 219 is lowered by the boat elevator 115 and the lower end opening of the outer tube 203 (that is, the lower end opening of the manifold 209) is opened. The boat 217 with processed wafers 200 charged therein is unloaded out of the outer tube 203 through the lower end opening of the outer tube 203 (boat unloading step). Then, the processed wafers 200 are discharged (transferred) out of the boat 217 (wafer discharging step).

### (3) Effects According to Present Embodiments

According to the present embodiments, it is possible to obtain one or more of the following effects.
(a) It is possible to improve the film properties.
(b) In particular, it is possible to suppress the oxidation of the surface of the barrier film (first metal-containing film).
(c) It is possible to improve barrier properties of the barrier film while suppressing the etching of the barrier film.
(d) It is possible to reduce a resistivity of a metal-containing film (that is, the second metal-containing film) formed on the barrier film.
(e) It is possible to improve the film properties of the metal-containing film formed on the barrier film.

### <Other Embodiments of Present Disclosure>

While the technique of the present disclosure is described in detail by way of the embodiments described above, the technique of the present disclosure is not limited thereto. The technique of the present disclosure may be modified in various ways without departing from the scope thereof.

### <Modified Example>

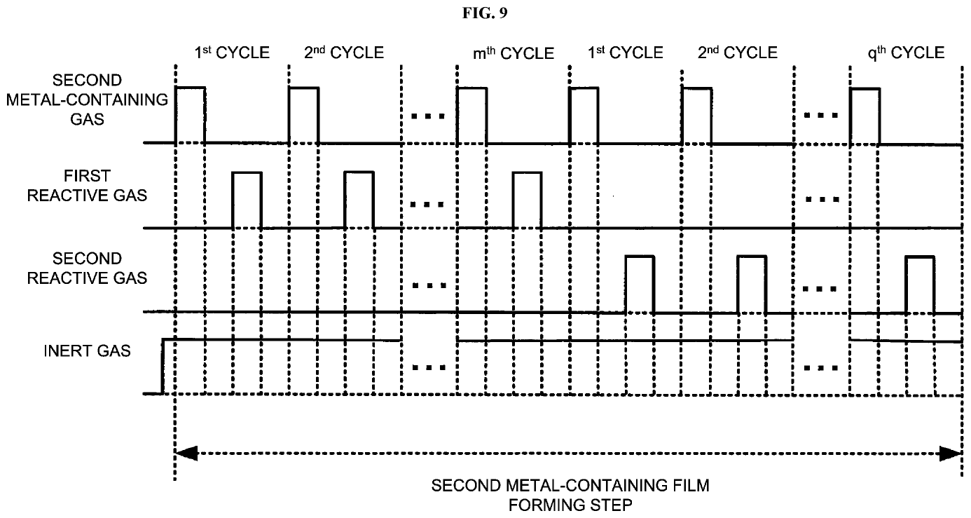

FIG. 9 is a diagram schematically illustrating a modified example of a process sequence of the substrate processing according to the embodiments of the present disclosure. A second metal-containing film forming step of the present modified example is different from that of the embodiments described above. That is, in the second metal-containing film forming step of the present modified example, by alternately and repeatedly supplying the second metal-containing gas and the first reactive gas such that the second metal-containing film of a predetermined thickness is formed on the wafer 200 while removing at least part of the cap film, and then, by alternately and repeatedly supplying the second metal-containing gas and a second reactive gas different from the first reactive gas, another film containing the second metal element is formed on the second metal-containing film. In the present modified example, the above-mentioned another film containing the second metal element formed on the second metal-containing film contains the second metal element contained in the second metal-containing film, and serves as a film whose resistivity is lower than that of the second metal-containing film. According to the present modified example, it is possible to form the second metal-containing film whose resistivity is low while removing at least part of the cap film.

According to the present modified example, in a case where the WF6 gas is used as the second metal-containing gas, the H2 gas serving as a first hydrogen-containing gas is used as the first reactive gas and diborane (B2H6) gas serving as a second hydrogen-containing gas is used as the second reactive gas, by supplying the WF6 gas and the H2 gas a predetermined number of times (m times), it is possible to form the tungsten (W) film (where the SiN and fluorine (F) remaining therein are low) on the wafer 200 while removing at least part of the SiN film serving as the example of the cap film formed on the first metal-containing film. Thereafter, by supplying the WF6 gas and the B2H6 gas a predetermined number of times (q times), it is possible to form the W film whose resistivity is low. That is, it is possible to form the second metal-containing film whose resistivity is low on the first metal-containing film while suppressing the etching of the first metal-containing film due to the formation of the second metal-containing film.

For example, the embodiments described above are described by way of an example in which the DCS gas is used as the gas containing the Group 13 element or the Group 14 element in the cap film forming step. However, the technique of the present disclosure is not limited thereto. For example, the technique of the present disclosure may also be applied when another gas is used as the gas containing the Group 13 element or the Group 14 element. For example, the technique of the present disclosure may also be applied when a gas such as hexachlorodisilane (Si2Cl6, abbreviated as: HCDS) gas is used as the gas containing the Group 13 element or the Group 14 element. In a case where the HCDS gas is supplied as the gas containing the Group 13 element or the Group 14 element and the NH3 gas is supplied as the third reactive gas, the Si2Cl6 reacts with the NH3. Thereby, SixNy, chlorine (Cl2) and hydrochloric acid (HCl) are generated. As a result, it is possible to form the SiN film serving as the cap film on the wafer 200 with the first metal-containing film formed on the surface thereof.

For example, the embodiments described above are described by way of an example in which the H2 gas is used as the first reactive gas in the second metal-containing film forming step. However, the technique of the present disclosure is not limited thereto. For example, the technique of the present disclosure may also be applied when another gas is used as the first reactive gas. For example, the technique of the present disclosure may also be applied when a gas containing silicon (Si) and hydrogen (H) such the monosilane (SiH4) gas and the disilane (Si2H6) gas is used as the first reactive gas. By using the gas containing silicon (Si) and hydrogen (H) such the monosilane (SiH4) gas as the first reactive gas, as compared with a case where the H2 gas is used as the first reactive gas as described above, it is possible to promote the reaction so as to increase a generation amount of the HF. As a result, it is possible to promote the etching (removal) of the SiN film by the HF.

For example, the technique of the present disclosure may also be applied when a gas containing boron (B) and hydrogen (H) such as the diborane (B2H6) gas and monoborane (BH3) gas is used as the first reactive gas in the second metal-containing film forming step. By using the gas containing boron (B) and hydrogen (H) such as the diborane (B2H6) gas as the first reactive gas, as compared with the case where the H2 gas is used as the first reactive gas as described above, it is possible to promote the reaction so as to increase the generation amount of the HF. As a result, it is possible to promote the etching (removal) of the SiN film by the HF. In addition, it is possible to reduce the resistivity of the second metal-containing film (such as the W film) formed on the first metal-containing film (such as the TiN film).

The SiH4 or the B2H6 exemplified in the present specification reacts more readily with the WF6 than the H2. Therefore, by using the SiH4 gas or the B2H6 gas as the first reactive gas, it is possible to promote the reaction with the WF6 so as to increase the generation amount of the HF. As a result, it is possible to promote the etching (removal) of the SiN film by the HF. Further, by the reaction between the WF6 and the SiH4 (or the B2H6), the W film may be formed before the SiN film is removed. As a result, the SiN film may remain under the W film. For example, in the case where the H2 gas is used as the first reactive gas, as compared with the case where the SiH4 gas or the B2H6 gas is used as the first reactive gas, the reaction with the WF6 is slow and an amount of the remaining SiN film is reduced.

For example, the embodiments described above are described by way of an example in which, after performing the first metal-containing film forming step and the cap film forming step in the same process furnace 202a (that is, in-situ), by performing the second metal-containing film forming step in the process furnace 202b (that is, ex-situ), the second metal-containing film is formed on the first metal-containing film while suppressing the oxidation of the surface of the first metal-containing film. However, the technique of the present disclosure is not limited thereto. For example, the second metal-containing film forming step may be performed continuously in the same process furnace (that is, the process furnace 202a) as the first metal-containing film forming step and the cap film forming step. That is, the wafer 200 with the cap film formed on the surface thereof may be continuously processed while being accommodated in the process chamber 201a without being taken out of the process chamber 201a. That is, the wafer 200 may be continuously processed in the same process chamber (that is, in-situ).

For example, the embodiments described above are described by way of an example in which the TiN film is used as the first metal-containing film. However, the technique of the present disclosure is not limited thereto. For example, the technique of the present disclosure may also be applied when another metal-containing film such as a molybdenum (Mo)-containing film, a ruthenium (Ru)-containing film and a copper (Cu)-containing film is used as the first metal-containing film.

For example, the embodiments described above are described by way of an example in which the SiN film is used as the cap film (that is, the film containing the Group 13 element or the Group 14 element). However, the technique of the present disclosure is not limited thereto. For example, the technique of the present disclosure may also be applied when a film containing another Group 13 element such as boron (B), aluminum (Al), gallium (Ga) and indium (In) or a film containing another Group 14 element such as silicon and germanium (Ge) is used as the cap film. For example, a nitride film such as an aluminum nitride (AlN) film may be used as the cap film instead of the SiN film. The films exemplified above can suppress the oxidation of the metal-containing film serving as the base film (underlying film), and can sublime and disappear when a metal-containing film different from the metal-containing film serving as the base film is formed on the cap film. The SiN film sublimates and disappears more easily than the AlN film.

For example, as the gas containing the Group 13 element (that is, a Group 13 element-containing gas), for example, a gas containing the Group 13 element exemplified above and at least one selected from the group consisting of hydrogen (H), the halogen element (such as fluorine (F) and chlorine (Cl)) and the alkyl group (for example, the methyl group (CH3)) may be used. As a gas containing aluminum (Al), for example, a gas such as trimethylaluminum (Al(CH3)3) gas and aluminum trichloride (AlCl3) gas may be used. By using the gases described above, it is possible to form the AlN film.

For example, the embodiments described above are described by way of an example in which the purge is performed between the steps in the second metal-containing film forming step. However, the technique of the present disclosure is not limited thereto. For example, the purge may not be performed between the steps in the second metal-containing film forming step. For example, the second metal-containing gas and the first reactive gas (or the second metal-containing gas and the second reactive gas) may be supplied simultaneously.

Examples of the embodiments will be described below. However, the technique of the present disclosure is not limited thereto.

### First Example

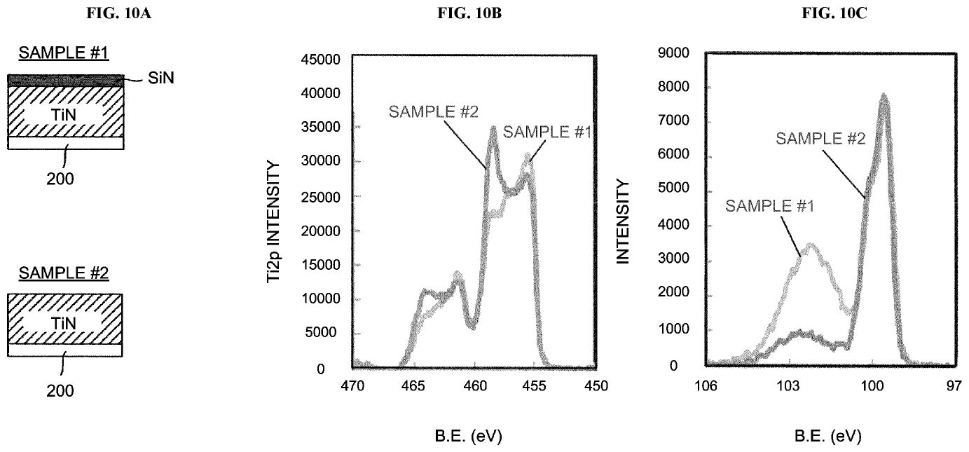

First, as shown in FIG. 10A, a sample #1 and a sample #2 are prepared by using the process furnace 202a of the substrate processing apparatus 10 described above. The sample #1 is prepared by forming the TiN film on the wafer 200 and the SiN film serving as the cap film on the TiN film. The sample #1 is prepared by performing the first metal-containing film forming step and the cap film forming step in a process sequence of the substrate processing described above shown in FIG. 6. The sample #2 is prepared by forming the TiN film on the wafer 200. The sample #2 is prepared by performing the first metal-containing film forming step alone in the process sequence of the substrate processing described above shown in FIG. 6. Then, an XPS (X-ray Photoelectron Spectroscopy) analysis is performed on a surface of each of the sample #1 and the sample #2.

As shown in FIGS. 10B and 10C, it is confirmed that a peak value of the sample #1 is different from a peak value of the sample #2, and that, by forming the cap film on the TiN film, it is possible to suppress TiO components, and thereby, it is also possible to suppress the oxidation of the TiN film.

### Second Example

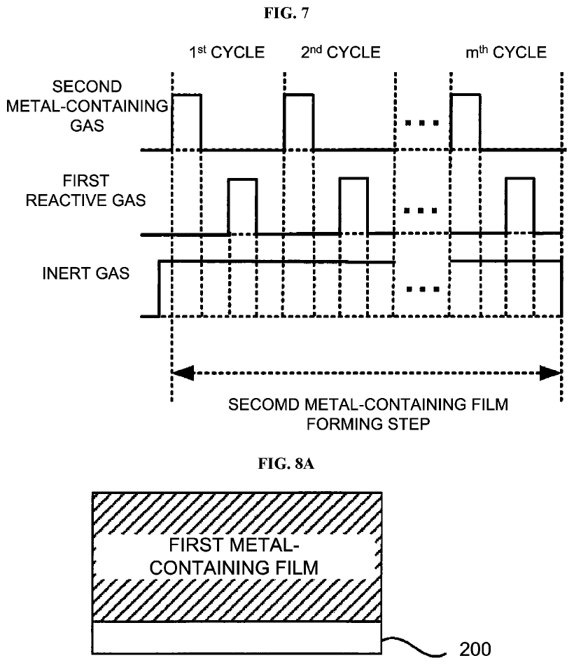

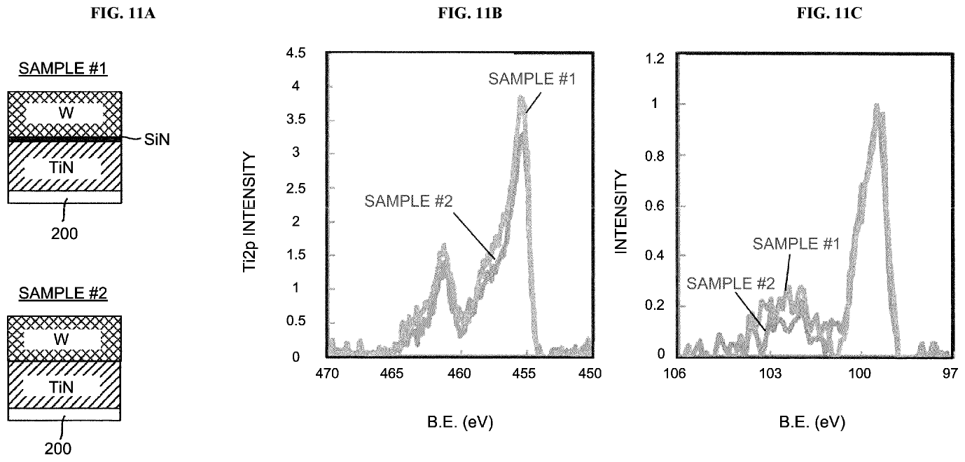

Subsequently, as shown in FIG. 11A, by using the process furnace 202b of the substrate processing apparatus 10 described above, the W film is formed on the surface of each of the sample #1 and the sample #2. The W film is formed by performing a process sequence of the substrate processing described above shown in FIG. 7. Then, the XPS (X-ray Photoelectron Spectroscopy) analysis is performed on the surface of each of the sample #1 and the sample #2 with the W film formed thereon.

As shown in FIG. 11B, it is confirmed that a Ti2p intensity of the sample #1 is higher than that of the sample #2, and a large amount of the TiN film remains in the sample #1. That is, it is confirmed that the etching of the TiN film is suppressed during a formation of the W film by forming the cap film. Further, as shown in FIGS. 10C and 11C, it is confirmed that a peak value of the cap film disappeared, and that the cap film is removed by forming the W film on the cap film.

While the technique of the present disclosure is described in detail by way of the embodiments and the examples described above, the technique of the present disclosure is not limited thereto. The technique of the present disclosure may be applied even when the embodiments and the examples described above are appropriately combined.

According to some embodiments in the present disclosure, it is possible to improve the film properties.

What is claimed is:

1. A substrate processing method comprising:
(A) preparing a substrate comprising a first film containing a first metal element and a second film containing a Group 13 element or a Group 14 element and formed on the first film; and
(B) forming a third film containing a second metal element on the substrate while removing at least part of the second film by performing:
(a) supplying a gas containing the second metal element to the substrate; and
(b) supplying a first reactive gas to the substrate.

2. The substrate processing method of claim 1, wherein the first reactive gas comprises a reducing gas.

3. The substrate processing method of claim 1, wherein the first reactive gas comprises a hydrogen-containing gas.

4. The substrate processing method of claim 3, wherein the hydrogen-containing gas comprises a hydrogen gas.

5. The substrate processing method of claim 1, wherein the first reactive gas comprises a gas containing silicon and hydrogen.

6. The substrate processing method of claim 1, wherein the first reactive gas comprises a gas containing boron and hydrogen.

7. The substrate processing method of claim 1, further comprising
(C) forming, after (B), a fourth film containing the second metal element on the third film by performing:
(a) supplying the gas containing the second metal element to the substrate; and
(c) supplying a second reactive gas different from the first reactive gas to the substrate.

8. The substrate processing method of claim 7, wherein the first reactive gas comprises a first hydrogen-containing gas, and the second reactive gas comprises a second hydrogen-containing gas.

9. The substrate processing method of claim 1, wherein, in (b), a flow rate of the first reactive gas is set to be smaller than a flow rate of the gas containing the second metal element, and after a predetermined time has elapsed, the flow rate of the first reactive gas is changed to a flow rate substantially same as the flow rate of the gas containing the second metal element.

10. The substrate processing method of claim 1, wherein (A) comprises forming the second film on the first film by performing:
(d) supplying a gas containing the Group 13 element or the Group 14 element to the substrate on which the first film is formed; and
(e) supplying a third reactive gas to the substrate.

11. The substrate processing method of claim 10, wherein (d) and (e) are repeatedly performed n times in the forming the second film on the first film, and
(a) and (b) are repeatedly performed m times in (B), m being greater than n.

12. The substrate processing method of claim 1, wherein a thickness of the second film in (A) is equal to or higher than 0.2 nm and equal to or lower than 3 nm.

13. The substrate processing method of claim 1, wherein a thickness of the second film in (A) is equal to or higher than 0.2 nm and equal to or lower than 2 nm.

14. The substrate processing method of claim 1, wherein a thickness of the second film in (A) is equal to or higher than 0.4 nm and equal to or lower than 1.8 nm.

15. The substrate processing method of claim 1, wherein a thickness of the second film in (A) is equal to or higher than one atomic layer and equal to or lower than several atomic layers.

16. A non-transitory computer-readable recording medium storing a program that causes a substrate processing apparatus, by a computer, to perform:
(A) preparing a substrate comprising a first film containing a first metal element and a second film containing a Group 13 element or a Group 14 element formed on the first film; and
(B) forming a third film containing a second metal element on the substrate while removing at least part of the second film by performing:
(a) supplying a gas containing the second metal element to the substrate; and
(b) supplying a first reactive gas to the substrate.

17. A substrate processing apparatus comprising:
a gas supplier configured for a gas containing a second metal element and a first reactive gas are to be supplied from the gas supplier to a substrate comprising a first film containing a first metal element and a second film containing a Group 13 element or a Group 14 element formed on the first film; and
a controller configured to be capable of controlling the gas supplier to perform:
(A) preparing the substrate; and
(B) forming a third film containing the second metal element on the substrate while removing at least part of the second film by performing:
(a) supplying the gas containing the second metal element to the substrate; and
(b) supplying the first reactive gas to the substrate.

18. A method of manufacturing a semiconductor device comprising the substrate processing method of claim 1.
